(19) United States
(12) Patent Application Publication
(10) Pub. No.: US 2012/0099263 A1
(43) Pub. Date: Apr. 26, 2012

(54) Protective Device for an Electronic Apparatus

(75) Inventor: Jia-Bao Lin, Taichung Hsien (TW)

(73) Assignee: SUNREX TECHNOLOGY CORP., Taichung Hsien (TW)

(21) Appl. No.: 12/910,321

(22) Filed: Oct. 22, 2010

(51) Int. Cl. H05K 5/02

(52) U.S. Cl. 361/679.09

(57) ABSTRACT

A protective device for an electronic apparatus includes: a case including a base plate, and a surrounding frame member peripherally extending from the base plate and defining a receiving space with the base plate, the receiving space having an opening opposite to the base plate; a cover unit detachably connected to the case and having a top surface covering the receiving space; two fastening units, each of which is connected between the case and the cover unit; and an input device disposed on the top surface of the cover unit.

### BACKGROUND OF THE INVENTION

1. Field of the Invention

This invention relates to a protective device for an electronic apparatus, more particular to a protective device for an electronic apparatus provided with an input device.

2. Description of the Related Art

Referring to FIG. 1, a known protective device for an electronic apparatus, such as the protective device disclosed in Taiwanese Utility Model Publication No. 573902, comprises a base plate 11, a plurality of surrounding frame members 12 peripherally extending from the base plate 11, a plurality of blockers 13 respectively connected to the surrounding frame members 12, and a male fastener 14 connected to one of the blockers 13. The base plate 11, the surrounding frame members 12, and the blockers 13 cooperatively define a receiving space 15 for receiving the electronic apparatus 16 which has a female fastener 161. The electronic apparatus 16 is securely received in the receiving space 15 through engagement of the male fastener 14 of the protective device with the female fastener 161 of the electronic apparatus 16.

However, the aforesaid protective device is not suitable for an electronic apparatus requiring an input device, such as a tablet computer. Since the user has to carry an input device in addition to the protective device in which the electronic apparatus is received, the electronic apparatus and the input device may collide with each other and be exposed to unavoidable damage.

### SUMMARY OF THE INVENTION

Therefore, an object of the present invention is to provide a protective device that is able to receive and protect an electronic apparatus and that is provided with an input device.

According to the present invention, a protective device for an electronic apparatus comprises: a case including a base plate, and a surrounding frame member peripherally extending from the base plate and defining a receiving space with the base plate, the receiving space having an opening opposite to the base plate; a cover unit detachably connected to the case and having a top surface covering the receiving space; two fastening units, each of which is connected between the case and the cover unit; and an input device disposed on the top surface of the cover unit.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is an exploded perspective view showing a conventional protective device for an electronic apparatus;

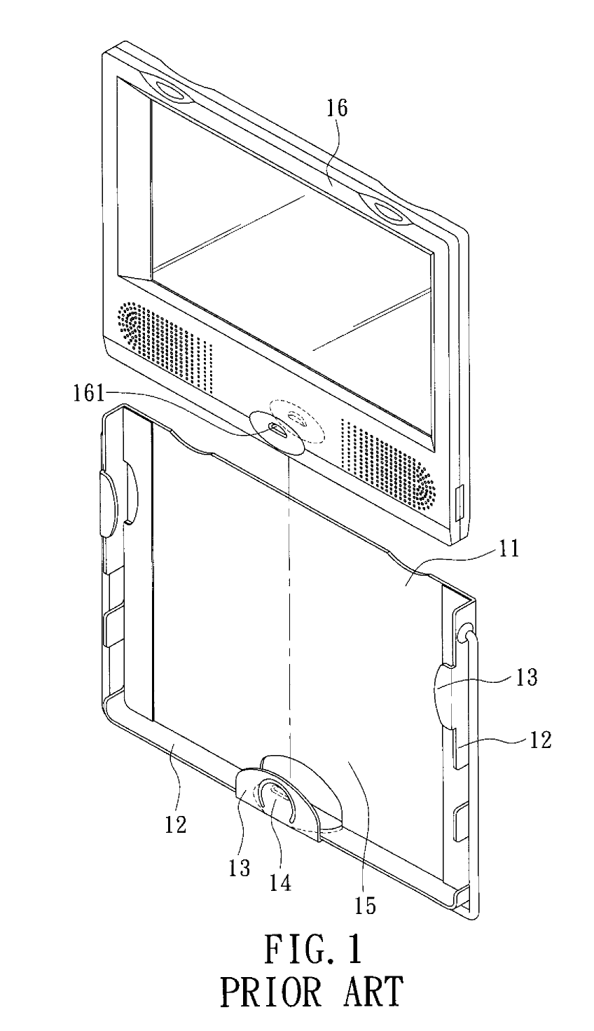

FIG. 2 is a perspective view of the preferred embodiment of a protective device for an electronic apparatus according to this invention;

FIG. 3 is an exploded perspective view of the preferred embodiment;

FIG. 4 is a perspective view showing a case of the preferred embodiment;

FIG. 5 is an exploded perspective view showing a cover unit and two fastening units of the preferred embodiment;

FIG. 6 is a top view showing a cover unit of the preferred embodiment;

FIG. 7 is a fragmentary cross sectional view of the preferred embodiment with an electronic apparatus received therein;

FIG. 8 is a perspective view showing the case of the preferred embodiment in a state of use; and

FIG. 9 is a fragmentary cross sectional view showing the preferred embodiment in a state of use.

### DETAILED DESCRIPTION OF THE PREFERRED EMBODIMENT

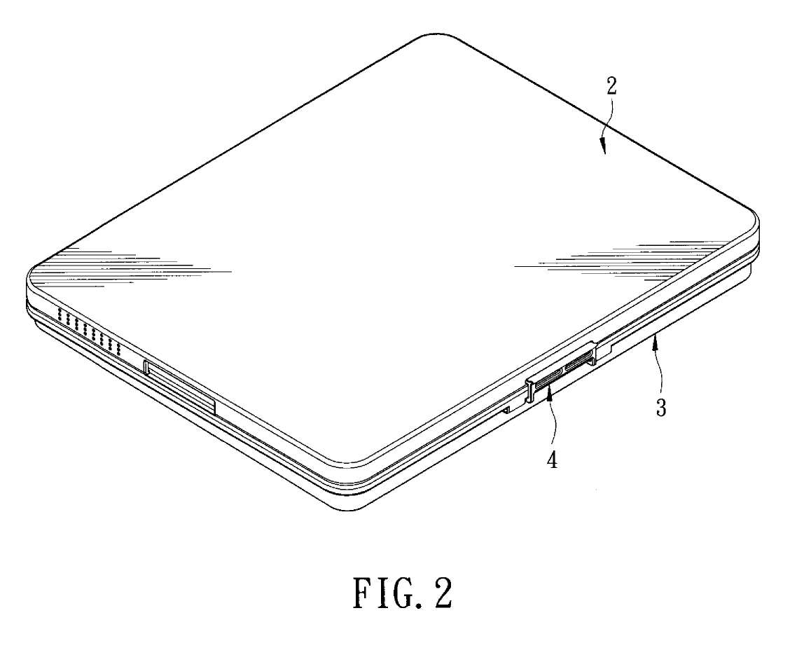

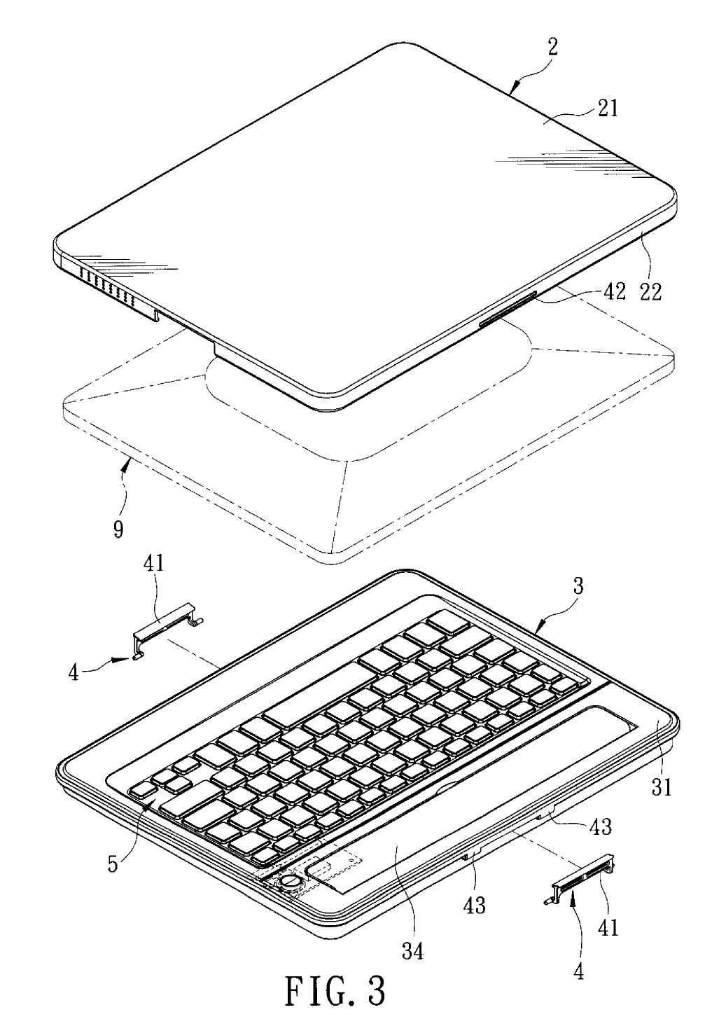

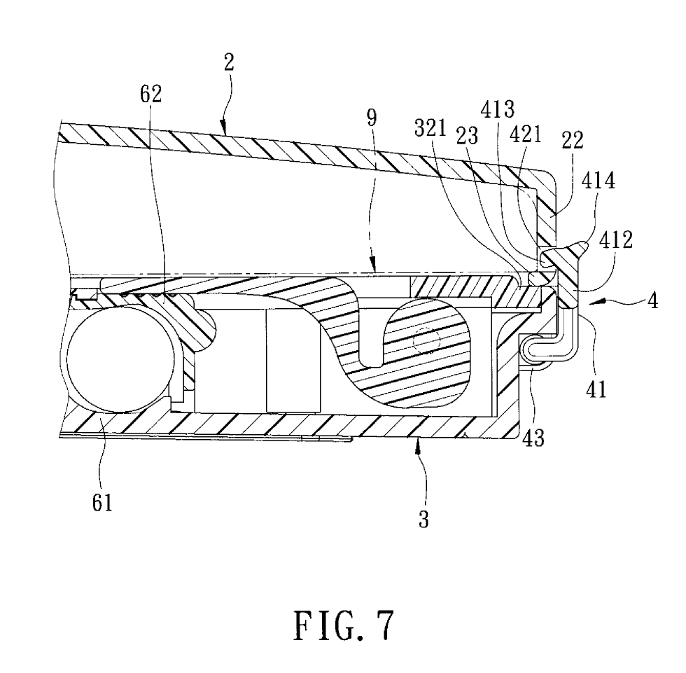

Referring to FIGS. 2 to 5, the preferred embodiment of a protective device for an electronic apparatus of the present invention comprises a case 2, a cover unit 3, two fastening members 4, and an input device 5. Further referring to FIG. 7, the phantom lines shown in FIGS. 3 and 7 represent an electronic apparatus 9, e.g., a tablet computer.

The case 2 includes a base plate 21, a surrounding frame member 22 peripherally extending from the base plate 21 and defining a receiving space 8 with the base plate 21, and a flange portion 23 projecting from the surrounding frame member 22 oppositely of the base plate 21 and toward the receiving space 8. The receiving space 8 has an opening 81 opposite to the base plate 21.

Preferably, a plurality of terminal grooves 24 are formed in the flange portion 23 and the surrounding frame member 22. These terminal grooves 24 are adapted to receive terminals of the electronic apparatus 9 (not shown).

Referring to FIGS. 3 to 6, the cover unit 3 is detachably connected to the case 2 and has a top surface 32 covering the receiving space 8. Preferably, the cover unit 3 includes a mounting region 31 formed with a mounting recess 33 opening at the top surface 32, and a pivotable lid 34 pivotally connected to the mounting region 31 to cover the mounting recess 33. More preferably, the cover unit 3 further includes a blocking wall 35 bounding one side of the mounting recess 33, and two side blockers 36 projecting into the mounting recess 33 from the blocking wall 35. The blocking wall 35 has a middle cutout 351. In particular, the side blockers 36 extend along the longitudinal direction of the mounting recess 33.

Further referring to FIG. 7, the top surface 32 of the cover unit 3 includes an outer peripheral portion 321 abutting against the flange portion 23 of the case 2, an inner portion 322 protruding upwardly from and surrounded by the outer peripheral portion 321, and an indented portion 323 surrounded by and indented from the inner portion 322 to receive the input device 5.

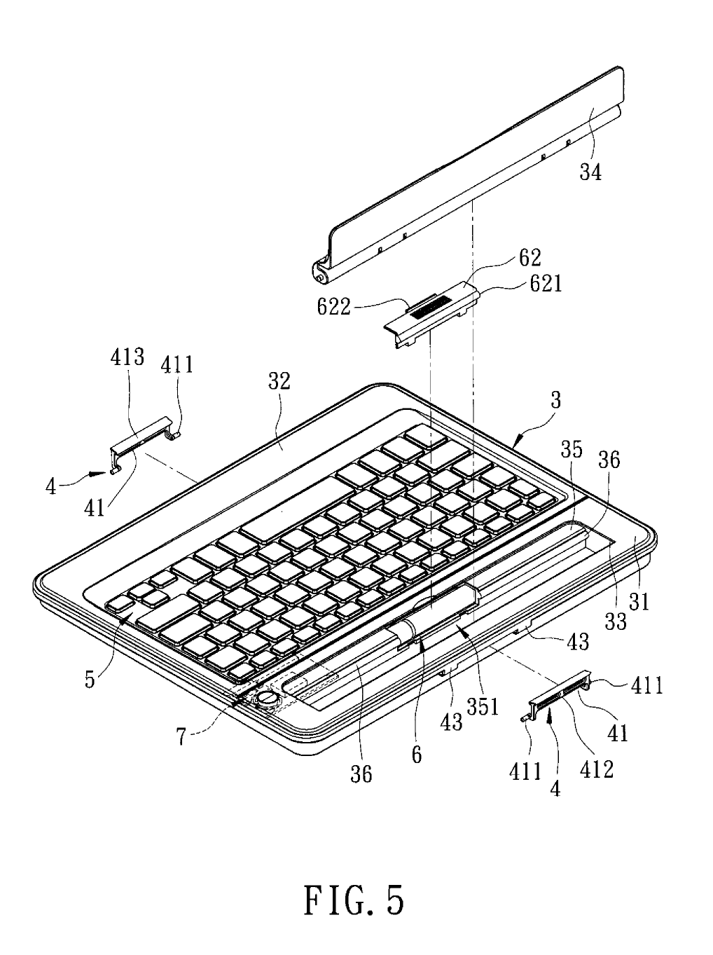

Referring back to FIGS. 3 and 5, the two fastening units 4 are respectively connected between the case 2 and the cover unit 3 and disposed on two opposite sides of the case 2 and two opposite sides of the cover unit 3. Each of the fastening units 4 includes a male fastener 41 disposed on the cover unit 3, a female fastener 42 disposed on the case 2 to engage the male fastener 41, and a pair of ear portions 43 disposed on the corresponding one of the opposite sides of the cover unit 3.

Further referring to FIG. 7, the male fastener 41 of each of the fastening units 4 has a pair of pivot pins 411 respectively and pivotally connected to the ear portions 43, a connecting portion 412 connected between the pivot pins 411, an engaging portion 413 projecting from the connecting portion 412, and a toggle portion 414 disposed on the connecting portion 412 opposite to the engaging portion 413. The female fastener 42 of each of the fastening units 4 has an engaging slot 421 formed in the surrounding frame member 22 of the case 2 to engage the engaging portion 413 of the male fastener 41.

Referring to FIGS. 5 to 7, the input device 5 is disposed on the top surface 32 of the cover unit 3. In this preferred embodiment, the input device 5 is a keyboard having a keyboard surface not higher than the inner portion 322 of the top surface 32 of the cover unit 3. Alternatively, the input unit 5 may be one of a touch pad, a track ball, a touch keyboard, and combinations thereof.

Preferably, the protective device of this invention further includes a battery module 6. The battery module 6 is disposed adjacent to the mounting recess 33 of the cover unit 3, and includes a battery chamber 61 adapted for receiving battery cells, and a battery lid 62 for covering the battery chamber 61. The battery lid 62 has a portion 622 that extends into the middle cutout 351 of the blocking wall 35 of the cover unit 3 and that has a central blocker 621 protruding from the battery lid 62 to be interposed between the side blockers 36.

Preferably, the protective device of this invention further includes a wireless transmission module 7. The wireless transmission module 7 is disposed in the mounting region 31 of the cover unit 3 and powered by the battery module 6 so as to transmit the input data from the input device 5 to the electronic apparatus 9. In this preferred embodiment, the wireless transmission module 7 may be a Bluetooth module or an infrared module.

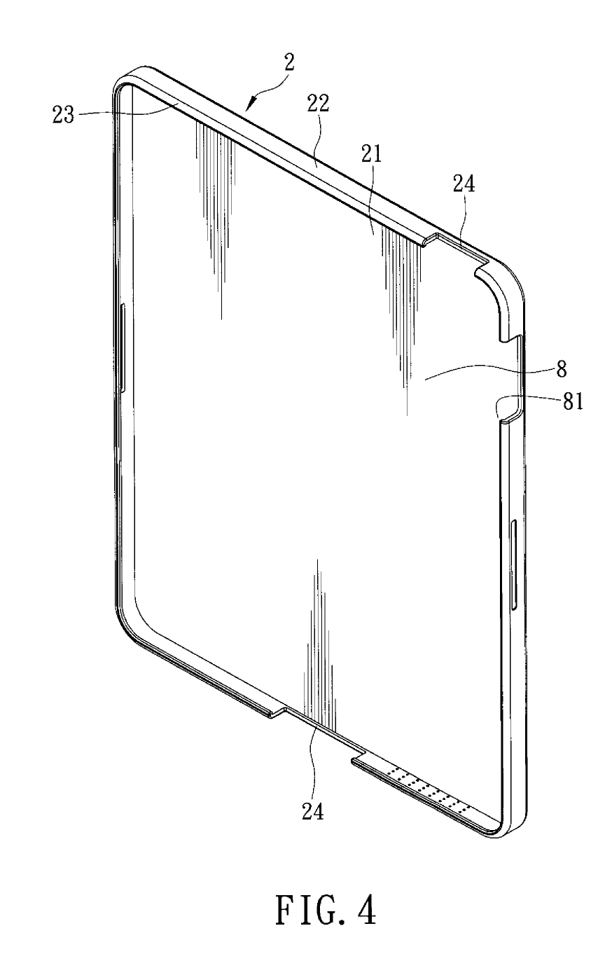

Referring to FIGS. 3 and 4, when the protective device is used together with the electronic apparatus 9, the electronic apparatus 9 received in the receiving space 8 is held in the case 2 by means of the flange portion 23 of the surrounding frame member 22, so as to be prevented from slipping out of the case 2.

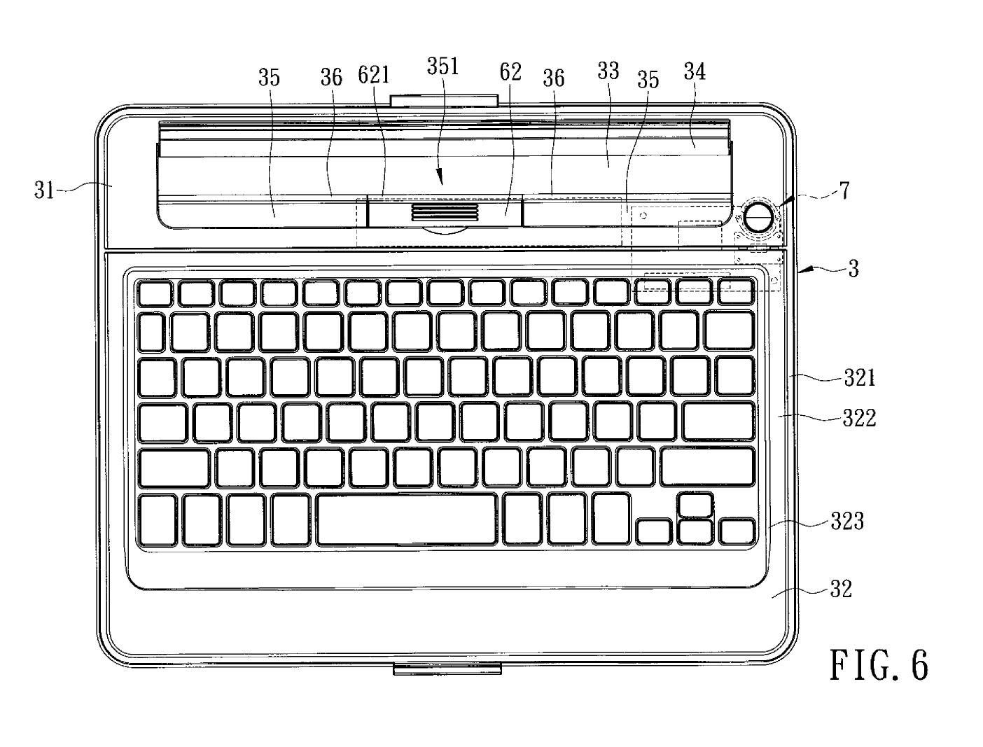

Further referring to FIGS. 6 and 7, when the electronic apparatus 9 received in the protective device is not in use, the cover unit 3 of the protective device covers the case 2 through abutment of the outer peripheral portion 321 of the cover unit 3 against the flange portion 23 of the case 2 so as to close the opening 81 of the receiving space 8. Besides, the male fasteners 4l disposed on the cover unit 3 may be pivoted relative to the corresponding ear portions 43 of the fastening units 4, and the engaging portions 413 of the male fasteners 41 may engage with the engaging slots 421 of the female fasteners 42. Consequently, the cover unit 3 is securely connected to the case 2 and the electronic apparatus 9 is safely received in the protective device and is prevented from slipping out of the receiving space 8.

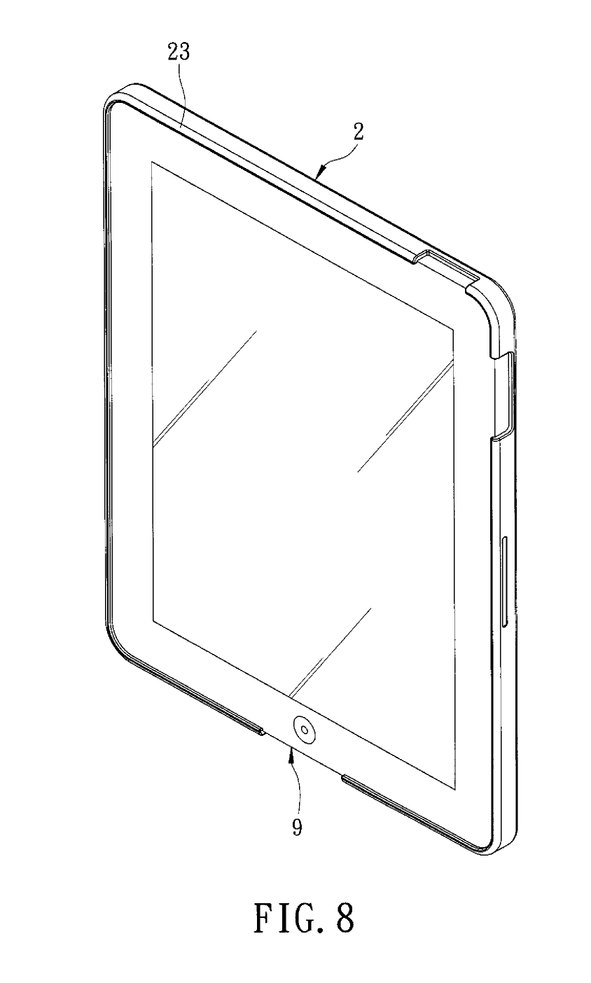

When the electronic apparatus 9 is in use, the cover unit 3 is detached from the case 2 by disengaging the engaging portions 413 of the male fasteners 41 from the engaging slots 421 of the female fasteners 42 through flipping the toggle portion 414. As shown in FIG. 8, the electronic apparatus 9 can be used by or displayed to the user when it is received and held stably in the receiving space 8 by the flange portion 23 of the case 2.

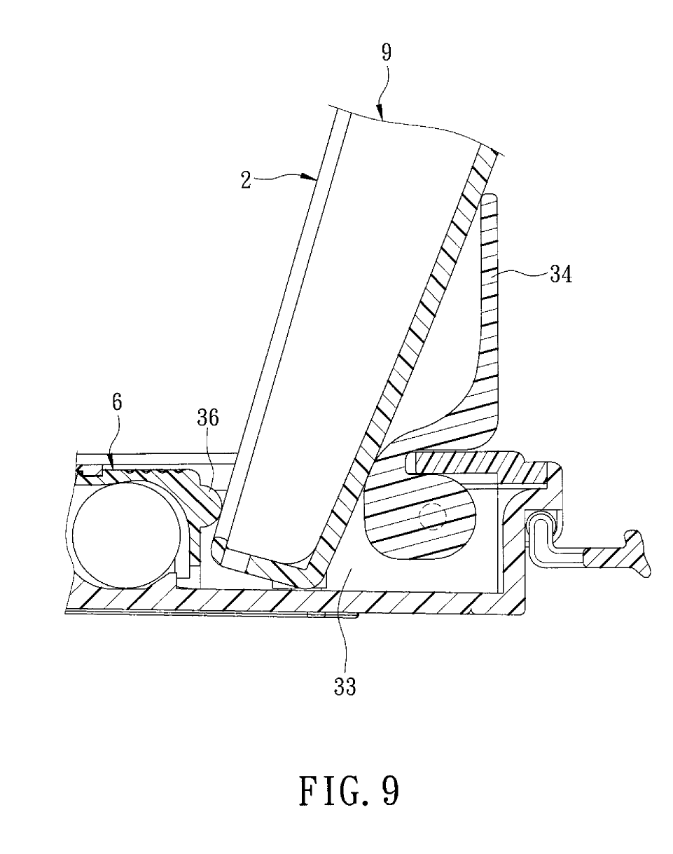

Further referring to FIGS. 3, 5, 6 and 9, when the input device 5 is required for inputting data while using the electronic apparatus 9, the pivotable lid 34 may be pivoted away from the mounting recess 33 and be disposed to serve as a backboard of the electronic apparatus 9. The electronic apparatus 9 with the case 2 may be inserted into the mounting recess 33 so as to lean against the backboard of the pivotable lid 34, and retained at an angle suitable for the user' s viewing by the side blockers 36. At the same time, the battery module 6 may be actuated to provide power to wirelessly transmit the input data from the input device 5 to the electronic apparatus 9 through the wireless transmission module 7.

Alternatively, the battery module 6 and the wireless transmission module 7 of the preferred embodiment may be replaced by a connecting terminal (not shown) disposed in the mounting recess 33 and electrically connected to the input device 5, so as to electrically connect the electronic apparatus 9 to the input device 5 through the connecting terminal.

Moreover, with the arrangement of the case 2, the cover unit 3 and the fastening units 4, when the electronic apparatus 9 is not in use, the electronic apparatus 9 and the input device 5 are separately held in the protective device at two opposite and immobile positions. Hence, they do not collide with each other so as to be prevented from damage when carrying. In addition, by virtue of rearranging the positions of the case 2 and the cover unit 3, the electronic apparatus 9 with the case 2 can be inserted into the mounting recess 33 and electrically connected to the input device 5 and receive the input data therefrom.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

What is claimed is:

1. A protective device for an electronic apparatus, comprising:
a case including a base plate, and a surrounding frame member peripherally extending from said base plate and defining a receiving space with said base plate, said receiving space having an opening opposite to said base plate;
a cover unit detachably connected to said case and having a top surface covering said receiving space;
two fastening units, each of which is connected between said case and said cover unit; and
an input device disposed on said top surface of said cover unit.

2. The protective device of claim 1, wherein said two fastening units are respectively disposed on two opposite sides of said case and two opposite sides of said cover unit, each of said fastening units including a male fastener disposed on said cover unit, and a female fastener disposed on said case to engage said male fastener.

3. The protective device of claim 2, wherein each of said fastening units further includes a pair of ear portions disposed on said corresponding one of the opposite sides of said cover unit, said male fastener of each of said fastening units having a pair of pivot pins respectively and pivotally connected to said ear portions, a connecting portion connected between said pivot pins, an engaging portion projecting from said connecting portion, and a toggle portion disposed on said connecting portion opposite to said engaging portion, said female fastener of each of said fastening units having an engaging slot formed in said surrounding frame member of said case to engage said engaging portion of said male fastener.

4. The protective device of claim 1, wherein said case further includes a flange portion projecting from said surrounding frame member oppositely of said base plate and toward said receiving space, said top surface of said cover unit including an outer peripheral portion abutting against said flange portion, an inner portion protruding upwardly from and surrounded by said outer peripheral portion, and an indented portion surrounded by and indented from said inner portion to receive said input device.

5. The protective device of claim 4, wherein said input device includes a keyboard having a keyboard surface not higher than said inner portion of said top surface of said cover unit.

6. The protective device of claim 1, wherein said cover unit includes a mounting region formed with a mounting recess, said mounting recess opening at said top surface of said cover unit.

7. The protective device of claim 6, wherein said cover unit further includes a pivotable lid pivotally connected to said mounting region to cover said mounting recess.

8. The protective device of claim 7, further comprising a battery module disposed adjacent to said mounting recess of said cover unit and a wireless transmission module disposed in said mounting region of said cover unit and powered by said battery module.

9. The protective device of claim 8, wherein said battery module includes a battery chamber adapted for receiving battery cells, and a battery lid for covering said battery chamber.

10. The protective device of claim 9, wherein said cover unit further includes a blocking wall bounding one side of said mounting recess, and two side blockers projecting into said mounting recess from said blocking wall, said blocking wall having a middle cutout, said battery lid having a portion that extends into said middle cutout and that has a central blocker protruding there from to be interposed between said side blockers.

11. The protective device of claim 6, further comprising a battery module disposed adjacent to said mounting recess of said cover unit and a wireless transmission module disposed in said mounting region of said cover unit and powered by said battery module.

12. The protective device of claim 11, wherein said battery module includes a battery chamber adapted for receiving battery cells, and a battery lid for covering said battery chamber.

13. The protective device of claim 12, wherein said cover unit further includes a blocking wall bounding one side of said mounting recess, and two side blockers projecting into said mounting recess from said blocking wall, said blocking wall having a middle cutout, said battery lid having a portion that extends into said middle cutout and that has a central blocker protruding therefrom to be interposed between said side blockers.
